(19) United States
(12) Patent Application Publication
(10) Pub. No.: US 2015/0068306 A1
(43) Pub. Date: Mar. 12, 2015

(54) MOVABLE DEVICE HAVING DROP RESISTIVE PROTECTION

(71) Applicant: Ming-Ching Wu, Taoyuan County (TW)

(72) Inventor: Ming-Ching Wu, Taoyuan County (TW)

(73) Assignee: GLOBALMEMS CO., LTD., Bandar Seri Begawan (BN)

(21) Appl. No.: 14/065,429

(22) Filed: Oct. 29, 2013

(30) Foreign Application Priority Data
Sep. 10, 2013 (TW) 102132602

(51) Int. Cl. B81B 7/00

(52) U.S. Cl. CPC B81B 7/0058; B81B 2201/0235
USPC 73/504.12

(57) ABSTRACT

A movable device including a base, a mass, a plurality of elastic portions and at least one block structure is provided. The mass has a plurality of side surfaces. The elastic portions are connected to the side surfaces respectively and connected to the base, where the mass is adapted to move such that the elastic portions are elastically deformed. The block structure is disposed at the base and aligned to at least one of the side surfaces, wherein the block structure is adapted to block the corresponding side surface to limit a moving range of the mass.

### CROSS-REFERENCE TO RELATED APPLICATION

This application claims the priority benefit of Taiwan application serial no. 102132602, filed on Sep. 10, 2013. The entirety of the above-mentioned patent application is hereby incorporated by reference herein and made a part of this specification.

### BACKGROUND

1. Technical Field

The invention relates to a movable device. Particularly, the invention relates to a movable device having drop resistive protection.

2. Related Art

In recent years, along with development of electronic products such as smart phones, tablet PCs and somatosensory game machines, etc., micro-electromechanical system (MEMS) inertial sensors such as accelerometers and gyroscopes, etc. are widely applied in the aforementioned electronic products, and a market demand thereof has grown significantly year by year. Under intense market competition, related applications of the MEMS inertial sensors have higher demand on quality of the MEMS inertial sensors. Regarding a piezo-resistive accelerometer, acceleration of an apparatus is measured through a resistance variation amount of a component therein.

FIG. 1 is a cross-sectional view of a conventional MEMS accelerometer. FIG. 2 is a top view of a part of components of the accelerometer of FIG. 1. Referring to FIG. 1 and FIG. 2, the conventional accelerometer 50 is, for example, a piezo-resistive accelerometer, in which a mass 52 is connected to a connection portion 56a of a base 56 through an elastic portion 54. When an apparatus having the accelerometer 50 withstands an external force, the mass 52 is moved and the elastic portion 54 is elastically deformed, and a resistance variation caused by the elastic deformation of the elastic portion 54 can be used to calculate an acceleration of the apparatus, and the detection and calculation principles are known techniques in the field. For example, U.S. Pat. No. 4,967,605 discloses related techniques of a MEMS accelerometer.

When the apparatus drops, if the mass 52 in the accelerometer 50 instantly generates a large displacement due to an impact force of the drop, the elastic portion 54 is probably damaged due to excessive pulling. In this way, in some drop resistive designs, a moving range of the mass 52 can be limited by decreasing a gap G1 between a first base body 56b and the mass 52 and decreasing a gap G2 between a second base body 56c and the mass 52, so as to avoid the mass 52 from instantly generating a large displacement due to the impact force caused by drop of the mass 52. However, along with miniaturization of the MEMS accelerometer, due to a size error generated when the first base body 56b and the second base body 56c are adhered to the connection portion 56a through an adhesive 58a and an adhesive 58b, the gap G1 and the gap G2 are hard to be accurately formed, such that the drop resistive protection cannot be substantially achieved, especially, there is none lateral drop resistive mechanism, which is a main damage mode of the product.

### SUMMARY

The invention is directed to a movable device, which has a good impact and drop resistive protection function.

The invention provides a movable device including a base, a mass, a plurality of elastic portions and at least one block structure. The mass has a plurality of side surfaces. The elastic portions are connected to the side surfaces respectively and connected to the base, where the mass is adapted to move such that the elastic portions are elastically deformed. The block structure is disposed at the base and is aligned to at least one of the side surfaces, where the block structure is adapted to block the corresponding side surface to limit a moving range of the mass.

In an embodiment of the invention, the base includes a first base body, a second base body and a connection portion. The mass is located between the first base body and the second base body, and the block structure is fixed to the first base body or the second base body. The connection portion is fixed between the first base body and the second base body, where each of the elastic portions is connected between the corresponding side surface and the connection portion.

In an embodiment of the invention, the connection portion is adhered to the first base body in a first direction, the connection portion is adhered to the second base body in the first direction, and each of the side surfaces is parallel to the first direction.

In an embodiment of the invention, a number of the at least one block structure is plural, and the block structures are respectively aligned to the side surfaces.

In an embodiment of the invention, the block structure has two block surfaces, and the two block surfaces are respectively aligned to the two adjacent side surfaces.

In an embodiment of the invention, the block structure extends from the base in a first direction, and a length of the block structure in the first direction is greater than a gap between the mass and the base in the first direction.

In an embodiment of the invention, the movable device further includes at least one block portion, where the mass has at least one end surface, the block portion is disposed on the base and extends towards the end surface and is aligned to the end surface, the mass is adapted to move in a first direction such that the elastic portions are elastically deformed, a gap between the base and the end surface in the first direction is greater than a gap between the block portion and the end surface in the first direction, and the block portion is adapted to block the end surface to limit the moving range of the mass.

In an embodiment of the invention, the block structure extends from the block portion.

In an embodiment of the invention, a length of the block structure in the first direction is greater than a gap of the block portion and the end surface in the first direction.

In an embodiment of the invention, a number of the at least one block portion is plural, and the at least one end surface includes a top surface of the mass and a bottom surface of the mass, a part of the block portions is aligned to the top surface, and another part of the block portions is aligned to the bottom surface.

In an embodiment of the invention, the mass has at least one end surface, the end surface is perpendicular to each of the side surfaces, the block structure is adapted to block the corresponding side surface to limit a moving range of the mass in a second direction, and the second direction is inclined to each of the side surfaces and the end surface.

In an embodiment of the invention, each of the elastic portions extends in an axis, and the axis does not pass through a mass center of the mass.

In an embodiment of the invention, the block structure is formed through an exposure process and an etching process.

According to the above descriptions, the movable device has block structures on the base, and the block structures are capable of blocking the side surfaces of the mass to limit the moving range of the mass, such that the mass is avoided to have an instant large displacement due to an impact force of drop, so as to avoid a pulling damage of the elastic portions due to excessive displacement of the mass. The block structures can be formed through an exposure process and an etching process to achieve a better size accuracy, such that the block structures and the side surfaces of the mass have suitable gaps there between to achieve an effect of accurately limiting the moving range of the mass, so as to improve the drop resistive protection function of the movable device.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional view of a conventional MEMS accelerometer.

FIG. 2 is a top view of a part of components of the accelerometer of FIG. 1.

FIG. 3 is a cross-sectional view of a movable device according to an embodiment of the invention.

FIG. 4 is a top view of a part of components of the movable device of FIG. 3.

FIG. 5 is a cross-sectional view of a movable device according to another embodiment of the invention.

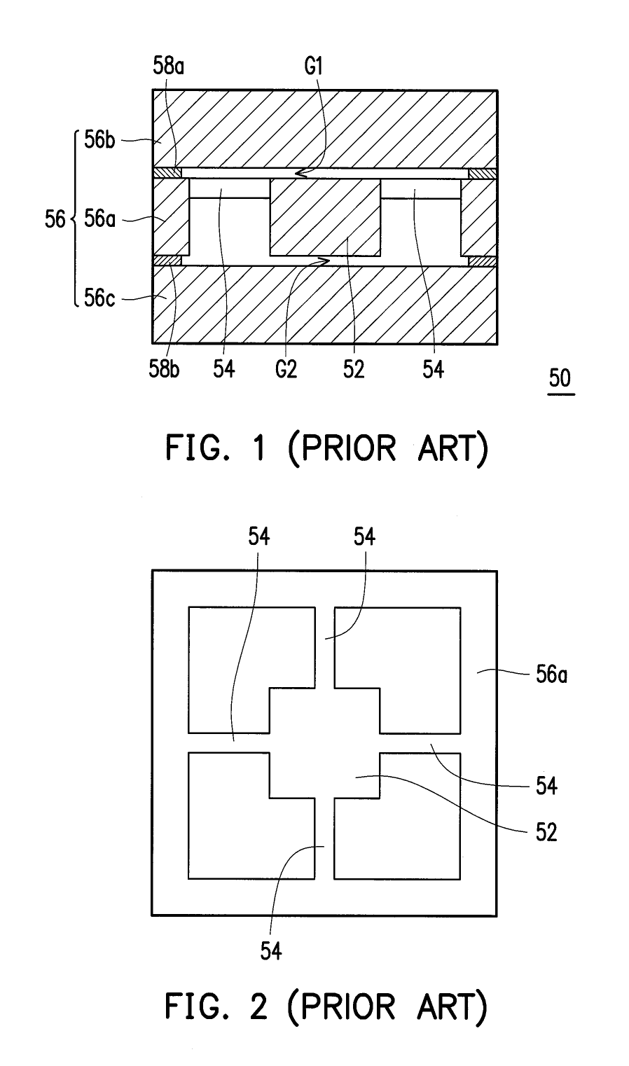

### DETAILED DESCRIPTION OF DISCLOSED EMBODIMENTS

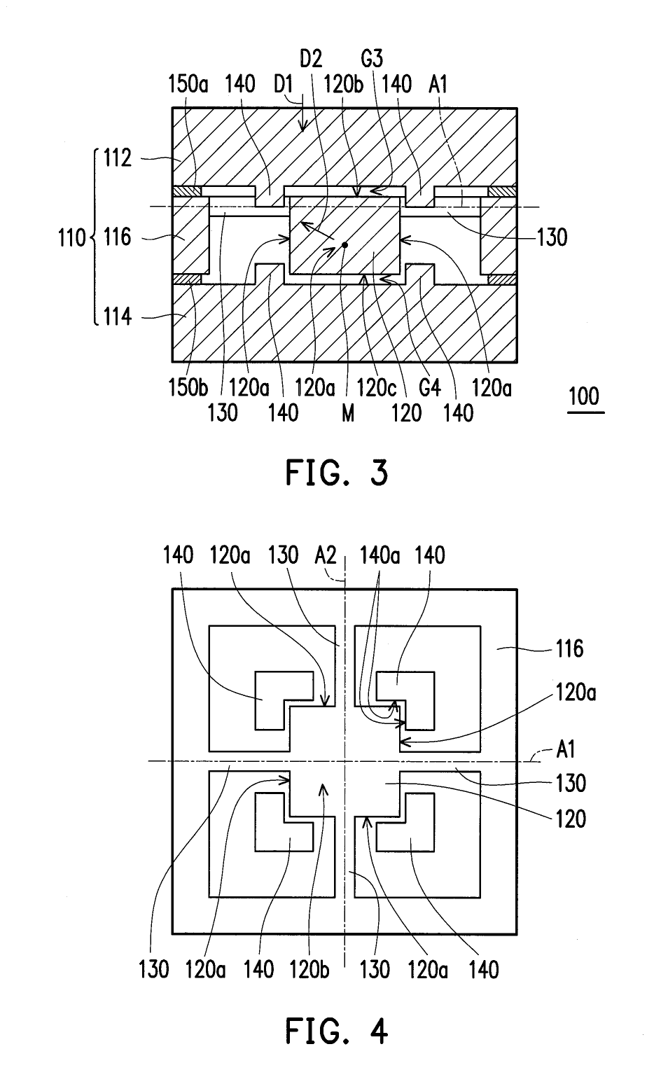

FIG. 3 is a cross-sectional view of a movable device according to an embodiment of the invention. FIG. 4 is a top view of a part of components of the movable device of FIG. 3. Referring to FIG. 3 and FIG. 4, the movable device 100 of the present embodiment is, for example, a MEMS accelerometer, and includes a base 110, a mass 120 and a plurality of elastic portions 130. The base 110 includes a first base body 112, a second base body 114 and a connection portion 116, where the connection portion 116 is fixed between the first base body 112 and the second base body 114. The mass 120 is located between the first base body 112 and the second base body 114 and has a plurality of side surfaces 120a and two end surfaces opposite to each other, where the two end surfaces are respectively a top surface 120b and a bottom surface 120c of the mass 120, which are perpendicular to each of the side surfaces 120a.

The elastic portions 130 are respectively connected to the side surfaces 120a and connected to the connection portion 116 of the base 110. When an apparatus having the accelerometer 100 withstands an external force, the mass 120 is moved and the elastic portions 130 are is elastically deformed, and a resistance variation caused by the elastic deformation of the elastic portions 130 can be used to calculate an acceleration of the apparatus, and detection and calculation principles thereof are known techniques in the field, which are not repeated.

The movable device 100 of the present embodiment further includes a plurality of block structures 140. A part of the block structures 140 is fixed to the first base body 112, and another part of the block structures 140 is fixed to the second base body 114. As that shown in FIG. 3, the block structures 140 extend from the base 110 in a first direction D1, and a length of each of the block structures 140 in the first direction D1 is greater than a gap G3 and a gap G4 between the mass 120 and the base 110 in the first direction D1, such that the block structures 140 can be respectively aligned to the side surfaces 120a of the mass 120, where each of the block structures 140, for example, has two block surfaces 140a, and the two block surfaces 140a are respectively aligned to two adjacent side surfaces 120a.

Under the above configuration, the block structures 140 can block the side surfaces 120a to limit a moving range of the mass 120, such that the mass 120 is avoided to have an instant large displacement due to an impact force of drop, so as to avoid a pulling damage of the elastic portions 130 due to excessive displacement of the mass 120. The block structures 140 can be formed through an exposure process and an etching process to achieve a better size accuracy, such that the block structures 140 and the side surfaces 120a of the mass 120 have suitable gaps there between to achieve an effect of accurately limiting the moving range of the mass 120, so as to improve the drop resistive protection function of the movable device 100.

Further, the connection portion 116 is adhered to the first base body 112 through an adhesive 150a in the first direction D1 shown in FIG. 3, the connection portion 116 is adhered to the second base body 114 through an adhesive 150b in the first direction D1, and each of the side surfaces 120a of the mass 120 is parallel to the first direction D1. In this way, a size error in the first direction D1 generated when the first base body 112 and the second base body 114 are adhered to the connection portion 116 is less likely to influence the accuracy of the gap between each of the side surfaces 120a and the corresponding block structure 140.

In the present embodiment, a part of the elastic portions 130 extends in an axis A1 (shown in FIG. 3 and FIG. 4), and another part of the elastic portions 130 extends in an axis A2 (which is only shown in FIG. 4), and the axis A1 and the axis A2 do not pass through a mass center M of the mass 120. In this way, when the mass 120 withstands the impact force of drop, the mass 120 is liable to have a displacement in an inclining direction. The inclining direction is, for example, the second direction D2 shown in FIG. 3 or other inclining directions inclined to the side surfaces 120a, the top surface 120b and the bottom surface 120c of the mass 120. When the mass 120 has a displacement in the inclining direction, the block structure 140 is adapted to block the side surface 120a of the mass 120 to limit the moving range of the mass 120 in the inclining direction, so as to avoid a pulling damage of the elastic portions 130 due to excessive displacement of the mass 120 in the first direction D1.

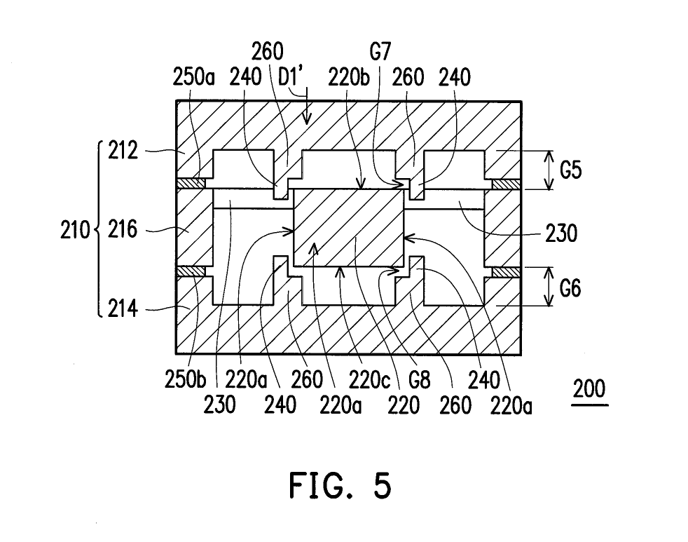

FIG. 5 is a cross-sectional view of a movable device according to another embodiment of the invention. In the movable device 200 of FIG. 5, configuration and functions of a base 210, a first base body 212, a second base body 214, a connection portion 216, a mass 220, elastic portions 230, block structures 240, an adhesive 250a and an adhesive 250b are similar to that of the base 110, the first base body 112, the second base body 114, the connection portion 116, the mass 120, the elastic portions 130, the block structures 140, the adhesive 150a and the adhesive 150b, which are not repeated. A difference between the movable device 200 and the movable device 100 is that the movable device 200 is integrated with a gyroscope function, and the mass 220 is further driven in a first direction D1′ to resonate to elastically deform the elastic portions 230, and a Coriolis force of the movable device 200 during rotation can be measured through the resonation operation method, so as to calculate an angular speed of an apparatus having the movable device 200, where the detection and calculation principles are known techniques in the field, which are not repeated.

The movable device 200 further includes a plurality of block portions 260, where a part of the block portions 260 is fixed to the first base body 212 and extends towards the top surface 220b of the mass 220 and is aligned to the top surface 220b, another part of the block portions 260 is fixed to the second base body 214 and extends towards the bottom surface 220c of the mass 220 and is aligned to the bottom surface 220c. A gap G5 between the base 210 and the top surface 220b of the mass 220 in the first direction D1′ is greater than a gap G7 between the block portion 260 and the top surface 220b of the mass 260 in the first direction D1′, and a gap G6 between the base 210 and the bottom surface 220c of the mass 220 in the first direction D1′ is greater than a gap G8 between the block portion 260 and the bottom surface 220c of the mass 260 in the first direction D1′.

Under such configuration, the block portion 260 is adapted to block the top surface 220b and the bottom surface of the mass 220 to limit the moving range of the mass 220, such that the mass 220 is avoided to have an instant large displacement due to an impact force of drop, so as to avoid a pulling damage of the elastic portions 230 due to excessive displacement of the mass 220, and achieve the drop resistive protection function. As that described above, in the movable device 200, since the block portion 260 on the base 210 is used to block the mass 220 to limit the moving range of the mass 220, it is unnecessary to decrease the gaps between the whole base 210 and the top surface 220b and the bottom surface 220c of the mass 220 for blocking the mass 220, such that the base 210 and the mass 220 may have larger gaps G5 and G6 there between. In this way, a damping effect caused by the air between the base 210 and the mass 220 is not excessive, so as to ensure a smooth resonance of the mass 220. In other embodiments, the movable device 200 can also be a quartz crystal oscillator or other resonance devices, which is not limited by the invention.

In the present embodiment, the block structures 240, for example, respectively extend from the block portions 260, and a length of the block structure 240 in the first direction D1 is greater than the gap G7 between the block portion 260 and the top surface 220b of the mass 220 in the first direction D1′ and is greater than the gap G8 between the block portion 260 and the bottom surface 220c of the mass 220 in the first direction D1′, such that the block structures 240 can be respectively aligned to the side surfaces 220a of the mass 220 to limit the moving range of the mass 220.

In summary, the movable device of the invention has block structures on the base, and the block structures are capable of blocking the side surfaces of the mass to limit the moving range of the mass, such that the mass is avoided to have an instant large displacement due to an impact force of drop, so as to avoid a pulling damage of the elastic portions due to excessive displacement of the mass. The block structures can be formed through an exposure process and an etching process to achieve a better size accuracy, such that the block structures and the side surfaces of the mass have suitable gaps there between to achieve an effect of accurately limiting the moving range of the mass, so as to improve the drop resistive protection function of the movable device. Moreover, the block portions can be configured on the base of the movable device for blocking the end surfaces of the mass to limit the moving range of the mass, so as to further improve the drop resistive protection function. By configuring the block portions, it is unnecessary to decrease the gaps between the base and the end surfaces of the mass for blocking the mass. In this way, a damping effect caused by the air between the base and the end surface of the mass is not excessive, so as to ensure a smooth resonance of the mass.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A movable device, comprising:
a base;
a mass, having a plurality of side surfaces;
a plurality of elastic portions, connected to the side surfaces respectively and connected to the base, wherein the mass is adapted to move such that the elastic portions are elastically deformed; and
at least one block structure, disposed at the base and aligned to at least one of the side surfaces, wherein the block structure is adapted to block the corresponding side surface to limit a moving range of the mass.

2. The movable device as claimed in claim 2, wherein the base comprises:
a first base body;
a second base body, wherein the mass is located between the first base body and the second base body, and the block structure is fixed to the first base body or the second base body; and
a connection portion, fixed between the first base body and the second base body, wherein each of the elastic portions is connected between the corresponding side surface and the connection portion.

3. The movable device as claimed in claim 2, wherein the connection portion is adhered to the first base body in a first direction, the connection portion is adhered to the second base body in the first direction, and each of the side surfaces is parallel to the first direction.

4. The movable device as claimed in claim 1, wherein a number of the at least one block structure is plural, and the block structures are respectively aligned to the side surfaces.

5. The movable device as claimed in claim 1, wherein the block structure has two block surfaces, and the two block surfaces are respectively aligned to the two adjacent side surfaces.

6. The movable device as claimed in claim 1, wherein the block structure extends from the base in a first direction, and a length of the block structure in the first direction is greater than a gap between the mass and the base in the first direction.

7. The movable device as claimed in claim 1, further comprising at least one block portion, wherein the mass has at least one end surface, the block portion is disposed on the base and extends towards the end surface to be aligned to the end surface, the mass is adapted to move in a first direction such that the elastic portions are elastically deformed, a gap between the base and the end surface in the first direction is greater than a gap between the block portion and the end surface in the first direction, and the block portion is adapted to block the end surface to limit the moving range of the mass.

8. The movable device as claimed in claim 7, wherein the block structure extends from the block portion.

9. The movable device as claimed in claim 8, wherein a length of the block structure in the first direction is greater than a gap of the block portion and the end surface in the first direction.

10. The movable device as claimed in claim 7, wherein a number of the at least one block portion is plural, the at least one end surface comprises a top surface of the mass and a bottom surface of the mass, a part of the block portions is aligned to the top surface, and another part of the block portions is aligned to the bottom surface.

11. The movable device as claimed in claim 1, wherein the mass has at least one end surface, the end surface is perpendicular to each of the side surfaces, the block structure is adapted to block the corresponding side surface to limit a moving range of the mass in a second direction, and the second direction is inclined to each of the side surfaces and the end surface.

12. The movable device as claimed in claim 1, wherein each of the elastic portions extends in an axis, and the axis does not pass through a mass center of the mass.

13. The movable device as claimed in claim 1, wherein the block structure is formed through an exposure process and an etching process.
